(19) United States
(12) Patent Application Publication
(10) Pub. No.: US 2024/0407089 A1
(43) Pub. Date: Dec. 5, 2024

(54) SILICA GLASS SUBSTRATE

(71) Applicant: AGC INC., Tokyo (JP)

(72) Inventors: Kent SUGA, Tokyo (JP); Hidetoshi MATSUMOTO, Tokyo (JP); Katsuaki MIYATANI, Tokyo (JP)

(73) Assignee: AGC INC., Tokyo (JP)

(21) Appl. No.: 18/804,505

(22) Filed: Aug. 14, 2024

Related U.S. Application Data
(63) Continuation of application No. PCT/JP2023/004264, filed on Feb. 8, 2023.

(30) Foreign Application Priority Data
Feb. 16, 2022 (JP) 2022-022213

(51) Int. Cl. H05K 1/03; C03B 19/14; C03C 11/00; H01L 23/15

(52) U.S. Cl. CPC H05K 1/0306; C03C 11/007; C03B 19/1453; C03B 2201/02; H01L 23/15; H05K 2201/0175

(57) ABSTRACT

The present invention relates to a silica glass substrate including: a first main surface and a second main surface that are facing each other, in which the silica glass substrate has a density of 2.0 g/cm3 or less, the silica glass substrate includes a plurality of bubbles, the silica glass substrate has an average diameter of first recessed portions of 30 μm or less, the first recessed portions being formed by the bubbles exposed on the first main surface, and the silica glass substrate has the number of the first recessed portions of 200/mm2 or less on the first main surface.

### CROSS-REFERENCE TO RELATED APPLICATIONS

This is a continuation of International Application No. PCT/JP2023/004264 filed on Feb. 8, 2023, and claims priority from Japanese Patent Application No. 2022-022213 filed on Feb. 16, 2022, the entire contents of which are incorporated herein by reference.

### TECHNICAL FIELD

The present invention relates to a silica glass substrate.

### BACKGROUND ART

High frequency devices require a substrate for making a circuit board, and a silica glass is known as an example of a material for such a substrate (for example, Patent Literature 1).

### CITATION LIST

### Patent Literature

Patent Literature 1: JP2017-228846A

### SUMMARY OF INVENTION

### Technical Problem

Generally, as a signal frequency increases, a signal transmission loss tends to increase in a circuit board. With respect to this, in the case where the circuit board is made from a substrate including a silica glass (hereinafter also referred to as a “silica glass substrate”), when a density of the silica glass substrate is reduced and a relative dielectric constant is reduced, it is possible to prevent an increase in signal transmission loss.

However, it has been difficult to obtain a silica glass substrate that has a small density and can be suitably used as a circuit board.

An object of the present invention is to obtain a silica glass substrate that has a small density and can be suitably used as a circuit board.

### Solution to Problem

A silica glass substrate according to one embodiment of the present invention includes: a first main surface and a second main surface that are facing each other, in which the silica glass substrate has a density of 2.0 g/cm³ or less, the silica glass substrate includes a plurality of bubbles, the silica glass substrate has an average diameter of first recessed portions of 30 μm or less, the first recessed portions being formed by the bubbles exposed on the first main surface, and the silica glass substrate has the number of the first recessed portions of 200/mm² or less on the first main surface.

### Advantageous Effects of Invention

According to one embodiment of the present invention, it is possible to obtain a silica glass substrate that has a small density and can be suitably used as a circuit board.

### BRIEF DESCRIPTION OF DRAWINGS

FIG. 1 is a perspective view schematically illustrating a silica glass substrate 10 according to a first embodiment.

FIG. 2 is a schematic diagram illustrating a cross-sectional SEM image of the silica glass substrate 10.

FIG. 3 is a perspective view schematically illustrating the silica glass substrate 10 according to a second embodiment.

FIG. 4 is a flowchart showing an example of a method for producing the silica glass substrate 10.

FIG. 5 is a schematic diagram illustrating a CO₂ laser device 40 according to one embodiment.

FIG. 6 is a schematic diagram illustrating an example of a beam scanning method using the CO₂ laser device 40.

FIG. 7 is a cross-sectional SEM image of the silica glass substrate 10 according to Example 1.

FIG. 8 is a cross-sectional SEM image of a silica glass sheet according to Example 3.

### DESCRIPTION OF EMBODIMENTS

Hereinafter, a specific example of a configuration according to an embodiment will be described with reference to the drawings.

In the following description, a numerical range represented by using “to” means a range including numerical values described before and after “to” as a lower limit value and an upper limit value. The lower limit value and the upper limit value include a rounding range.

In the drawings, unless otherwise specified, up-down and left-right positional relationships are based on positional relationships shown in the drawings, and dimensional ratios in the drawings are not limited to the ratios shown in the drawings. Note that, in the drawings, the same elements may be designated by the same reference numerals and redundant explanations may be omitted.

The “high frequency” refers to microwaves (3 GHz to 30 GHz) and millimeter waves (30 GHz to 300 GHz).

### <Silica Glass Substrate>

### First Embodiment

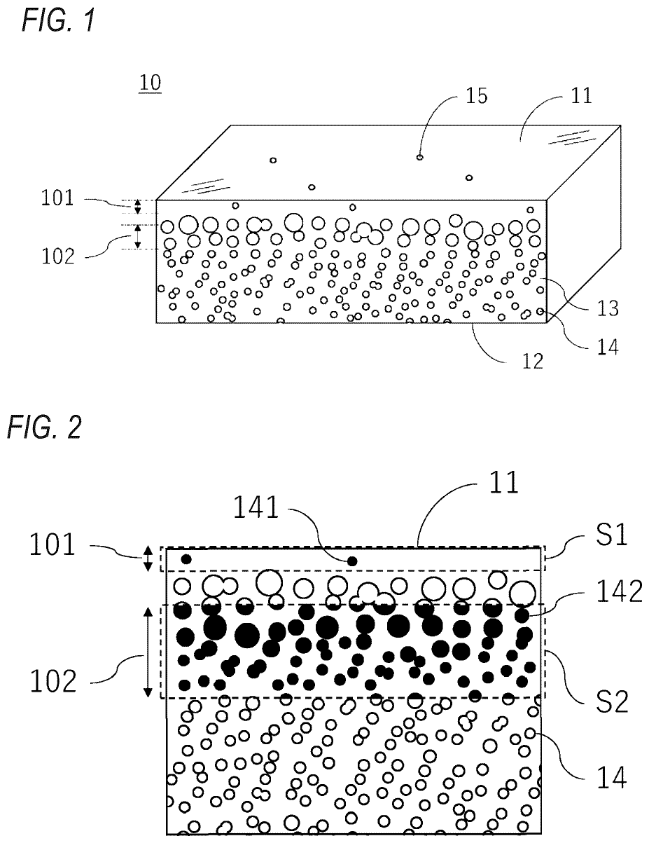

FIG. 1 is a perspective view schematically illustrating a silica glass substrate 10 according to a first embodiment. The silica glass substrate 10 includes a first main surface 11, a second main surface 12 facing the first main surface 11, a silica glass portion 13, bubbles 14, and first recessed portions 15 formed by the bubbles 14 exposed on the first main surface 11. In addition, the silica glass substrate 10 has a first region 101 having a depth of 4.93 μm or less from the first main surface 11 and a second region 102 having a depth of 19.7 μm to 200 μm from the first main surface 11. Note that, the “main surface” means a surface perpendicular to a thickness direction of the silica glass substrate 10.

The shape of the silica glass substrate 10 is a rectangular parallelepiped in FIG. 1, but the shape is not limited to the rectangular parallelepiped, and may be a disc shape or the like.

The silica glass portion 13 is transparent to visible light. On the other hand, the silica glass substrate 10 includes a plurality of bubbles 14 and is thus opaque to visible light as a whole. Note that, in the description, being “transparent” means that a visible light transmittance is 60% or more, preferably 70% or more, more preferably 80% or more, and still more preferably 90% or more.

The silica glass substrate 10 preferably has a thickness of 0.2 mm or more. When the thickness is 0.2 mm or more, the silica glass substrate 10 has sufficient mechanical strength and can thus be suitably used as a substrate for a high frequency device.

The thickness of the silica glass substrate 10 is preferably 4 mm or less, more preferably 3 mm or less, still more preferably 2 mm or less, even more preferably 1 mm or less, particularly preferably 0.8 mm or less, and extremely preferably 0.5 mm or less. When the thickness is 4 mm or less, the silica glass substrate 10 is suitable as a substrate for a high frequency device. Generally, in the high frequency device, a higher frequency requires a thinner substrate.

The thickness of the silica glass substrate 10 can be measured with a caliper or a tape measure.

The silica glass substrate 10 has a density of preferably 0.8 g/cm³ or more, more preferably 1.0 g/cm³ or more, still more preferably 1.2 g/cm³ or more, and particularly preferably 1.4 g/cm³ or more. When silica glass substrate 10 has the density of 0.8 g/cm³ or more, the silica glass substrate 10 has sufficient strength.

The density of the silica glass substrate 10 is preferably 2.0 g/cm³ or less, more preferably 1.8 g/cm³ or less, and still more preferably 1.75 g/cm³ or less. When the density of the silica glass substrate 10 is 2.0 g/cm³ or less, a relative dielectric constant of the silica glass substrate 10 can be reduced.

Note that, generally, it is known that the relative dielectric constant and the density of a silica glass are substantially proportional to each other. That is, the smaller the density of the silica glass substrate 10, the smaller the value of the relative dielectric constant of the silica glass substrate 10.

The density of the silica glass substrate 10 can be calculated by the Archimedes method using an electronic balance manufactured by Shimadzu Corporation (product name: UP423X) and a specific gravity measurement kit (product name: SMK-102) manufactured by Shimadzu Corporation on a test piece of about 3 g cut out from the silica glass substrate 10.

The silica glass substrate 10 has an OH-group content of preferably 100 ppm by mass or less, and more preferably 50 ppm by mass or less. When the OH-group content of the silica glass substrate 10 is 100 ppm by mass or less, a dielectric loss tangent of the silica glass substrate 10 can be reduced.

An OH-group content in the silica glass substrate 10 can be measured with an infrared spectrophotometer. Specifically, an IR spectrum of a test piece cut out from the silica glass substrate 10 is obtained using an infrared spectrophotometer, and then a peak derived from the OH group can be quantified and calculated (Reference: J. P. Williams et al., Direct determination of water in glass, Ceramic. Bulletin., Vol. 55, No. 5, pp 524, 1976).

The relative dielectric constant of the silica glass substrate 10 is preferably 5 or less, more preferably 4 or less, and still more preferably 3 or less. When the relative dielectric constant of the silica glass substrate 10 is 5 or less, the silica glass substrate 10 is suitable as, for example, a substrate for an antenna in a high frequency device application.

The dielectric loss tangent of the silica glass substrate 10 is preferably 0.01 or less. When the dielectric loss tangent of the silica glass substrate 10 is 0.01 or less, a transmission loss can be reduced in the case where a transmission line is formed on a main surface of the silica glass substrate 10.

The relative dielectric constant and the dielectric loss tangent of the silica glass substrate 10 can be measured using a cavity resonator and a vector network analyzer in accordance with a method described in JIS-R1641 (2007).

### (First Main Surface)

The first main surface 11 is a main surface obtained by laser processing in a method for producing the silica glass substrate 10 to be described later, and includes the first recessed portions 15 formed by the bubbles 14.

The first main surface 11 has a surface roughness Ra of preferably 10 nm or less, more preferably 3 nm or less, and still more preferably 1 nm or less.

The above surface roughness Ra can be measured using an atomic force microscope (AFM). Specifically, scanning is performed with a cantilever (AC-55 manufactured by Olympus Corporation) using an atomic force microscope (Cypher ES manufactured by Oxford Instruments) over a target region (5 μm×5 μm) on the surface of a test piece cut out from the silica glass substrate 10, and the number of obtained data is determined as 512×512. This is performed on at least three target regions, and the average value thereof is defined as the surface roughness Ra.

### (Silica Glass Portion)

The silica glass portion 13 is a portion of the silica glass substrate 10 excluding the bubbles 14.

The silica glass portion 13 is made of a silica glass containing an amorphous silicon oxide (SiO₂) as a main component, and has a density of about 2.2 g/cm³.

The composition of the silica glass portion 13 is not particularly limited as long as it contains SiO₂ as a main component, and may contain, in addition to SiO₂, a trace amount of metal impurities generated during production. Examples of the metal impurities include lithium (Li), sodium (Na), magnesium (Mg), aluminum (Al), potassium (K), calcium (Ca), chromium (Cr), manganese (Mn), iron (Fe), nickel (Ni), copper (Cu), titanium (Ti), cobalt (Co), zinc (Zn), silver (Ag), cadmium (Cd), and lead (Pb).

The metal impurities contained in the silica glass portion 13 are preferably 0.5 ppm by mass or less, and more preferably 0.1 ppm by mass or less. When the metal impurities contained in the silica glass portion 13 are 0.5 ppm by mass or less, the silica glass substrate 10 has excellent heat resistance and chemical resistance.

The composition of the silica glass portion 13 can be determined by ICP emission spectroscopy or the like.

### (Bubble)

The silica glass substrate 10 includes a plurality of bubbles 14. The bubbles 14 are present in a substantially uniformly dispersed manner in the silica glass substrate 10 and contain a gas therein.

FIG. 1 illustrates the bubbles 14 in a front cross section of the silica glass substrate 10, but other cross sections obtained by cutting the silica glass substrate 10 along the thickness direction also have similar cross sections. Note that, in FIG. 1, the bubbles 14 appearing on a right side cross section of the silica glass substrate 10 are omitted.

The shape of the bubbles 14 is not particularly limited, and is substantially spherical or oblate. However, as also shown in FIG. 1, some of the bubbles 14 may communicate with adjacent bubbles 14 and deform.

The size of the bubbles 14 varies depending on the depth from the first main surface 11 due to the method for producing the silica glass substrate 10 to be described later. Hereinafter, the sizes of the bubbles 14 present in the first region 101 and the second region 102 will be described using FIG. 2.

FIG. 2 is a schematic diagram illustrating a cross-sectional SEM image of the silica glass substrate 10.

The cross-sectional SEM image is obtained by observing a cross section obtained by cutting the silica glass substrate 10 along the thickness direction thereof using a scanning electron microscope (SEM) (S-3400 manufactured by Hitachi High-Tech Corporation).

Here, as shown in FIG. 2, in the cross-sectional SEM image, a cross-sectional area of the first region 101 is defined as S₁ and a cross-sectional area of the second region 102 is defined as S₂. When the bubbles 14 included in the first region 101 are defined as bubbles 141 and the bubbles 14 included in the second region 102 are defined as bubbles 142, a total cross-sectional area of the bubbles 141 is defined as S_{b1} and a total cross-sectional area of the bubbles 142 is defined as S_{b2}. Note that, in FIG. 2, the bubbles 141 and the bubbles 142 are shown in black to distinguish them from the bubbles 14 that are not included in either the first region 101 or the second region 102. In addition, the bubbles 14 present on a boundary of the first region 101 or the second region 102 are divided to calculate the cross-sectional area.

A specific method for calculating S_{b1} and S_{b2} is as follows. That is, for the above cross-sectional SEM image (for example, 421 μm×316 μm) obtained from any cross section, image processing software (for example, WinROOF 2018) is used to determine the cross-sectional areas of each of all bubbles 141 and bubbles 142 included in the cross-sectional SEM image, and the total cross-sectional area of the bubbles 141 and the total cross-sectional area of the bubbles 142 are determined. This is performed on at least three cross-sectional SEM images obtained by observing different locations, and the average values thereof are defined as S_{b1} and S_{b2}.

S_{b1}/S₁ is preferably 0.15 or less, more preferably 0.13 or less, still more preferably 0.11 or less, even more preferably 0.09 or less, particularly preferably 0.07 or less, extremely preferably 0.05 or less, and most preferably 0. When S_{b1}/S₁ is 0.15 or less, the silica glass substrate 10 has high strength on a surface layer and can thus be subjected to, for example, a cleaning step used for ordinary silica glasses.

S_{b2}/S₂ is preferably 0.20 or more, more preferably 0.22 or more, still more preferably 0.24 or more, even more preferably 0.26 or more, particularly preferably 0.28 or more, and extremely preferably 0.3 or more. When S_{b2}/S₂ is 0.20 or more, the second region 102 has a sufficiently small value of density, and the relative dielectric constant can be made small.

S_{b2}/S₂ is preferably 0.8 or less, more preferably 0.7 or less, still more preferably 0.6 or less, and particularly preferably 0.5 or less. When S_{b2}/S₂ is 0.8 or less, there is no risk that the strength of the silica glass substrate 10 is impaired due to excessive inclusion of the bubbles 142.

(S_{b2}/S₂)/(S_{b1}/S₁) (hereinafter, also simply referred to as “X”) is preferably 1.3 or more, more preferably 1.5 or more, still more preferably 1.7 or more, particularly preferably 2.0 or more, and most preferably 2.5 or more. When X is 1.3 or more, the density of the silica glass substrate 10 can be reduced and the relative dielectric constant can be reduced while sufficiently preventing formation of recessed portions to be described later, so that the silica glass substrate 10 can be suitably used as a substrate for a high frequency device.

### (Recessed Portion)

The first recessed portions 15 are formed by the bubbles 14 exposed on the first main surface 11. Therefore, the surface of the first recessed portion 15 is curved surface obtained by cutting out a substantially spherical or oblate sphere.

The first recessed portions 15 have an average diameter of preferably 30 μm or less. When the average diameter of the first recessed portions 15 is 30 μm or less, in the case of forming a transmission line on the first main surface 11, occurrence of disconnection can be prevented.

The number of the first recessed portions 15 is preferably 200/mm² or less, more preferably 100/mm² or less, still more preferably 50/mm² or less, even more preferably 20/mm² or less, particularly preferably 10/mm² or less, even particularly preferably 5/mm² or less, and most preferably 1/mm² or less. When the number of the first recessed portions 15 is 200/mm² or less, in the case of forming a transmission line on the first main surface 11, occurrence of disconnection can be prevented.

The average diameter and the number of the first recessed portions 15 can be determined using a scanning electron microscope (SEM) and image analysis. Specifically, a SEM image (395 μm×296 μm) obtained by observing the first main surface 11 with a scanning electron microscope (SEM) (S-3400 manufactured by Hitachi High-Tech Corporation) is subjected to a binarization process using image processing software (for example, ImageJ). When a white region included in the obtained processed image is regarded as the first recessed portion 15, the number thereof and the average diameter in the case where the first recessed portion 15 is assumed to be a perfect circle are determined. This is performed on at least five SEM images obtained from any location on the first main surface 11, and the average value thereof is determined.

### Second Embodiment

The features of the first main surface 11 side of the silica glass substrate 10 have been described above. However, in production of the silica glass substrate 10, in the case of obtaining the second main surface 12, by performing the processing similar to the case of obtaining the first main surface 11, the second main surface 12 side of the silica glass substrate 10 may have the features similar to that of the first main surface 11 side. This will be described in detail below.

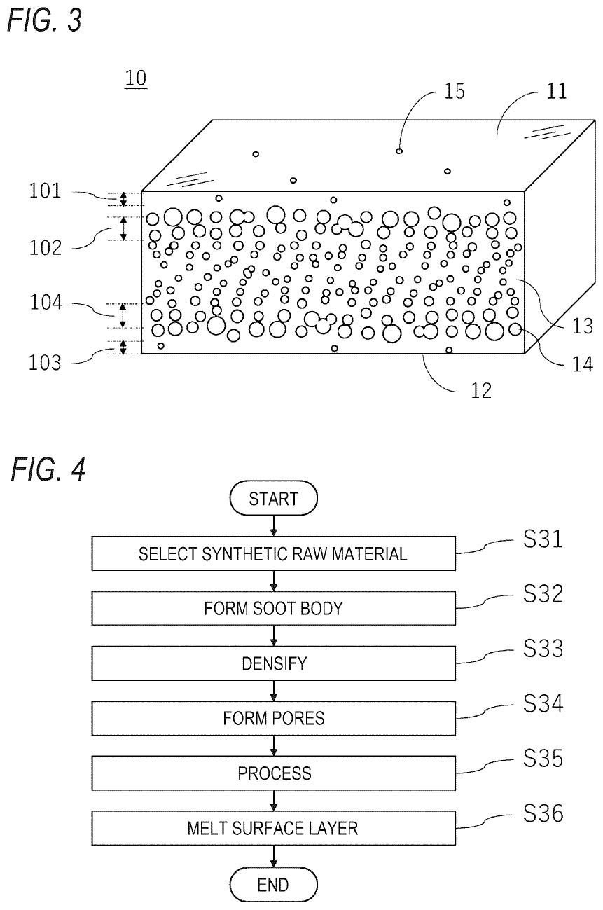

FIG. 3 is a perspective view schematically illustrating the silica glass substrate 10 according to a second embodiment. In addition to the first main surface 11, the second main surface 12, the silica glass portion 13, the bubbles 14, the first recessed portions 15, the first region 101, and the second region 102 described above, the silica glass substrate 10 further includes the following. That is, second recessed portions 16 (not shown) formed by the bubbles 14 exposed on the second main surface 12, a third region 103 having a depth of 4.93 μm or less from the second main surface 12, and a fourth region 104 having a depth of 19.7 μm to 200 μm from the second main surface 12.

The common configuration features of the silica glass substrate 10 according to the first embodiment and the silica glass substrate 10 according to the second embodiment are as described above. Hereinafter, features only possessed by the silica glass substrate 10 according to the second embodiment will be described.

### (Thickness)

The silica glass substrate 10 according to the second embodiment preferably has a thickness of 0.4 mm or more. When the thickness is 0.4 mm or more, the silica glass substrate 10 according to the second embodiment has sufficient mechanical strength and can thus be suitably used as a substrate for a high frequency device.

The thickness of the silica glass substrate 10 according to the second embodiment is preferably 4 mm or less, more preferably 3 mm or less, still more preferably 2 mm or less, even more preferably 1 mm or less, particularly preferably 0.8 mm or less, and extremely preferably 0.5 mm or less. When the thickness is 4 mm or less, the silica glass substrate 10 according to the second embodiment is suitable as a substrate for a high frequency device. Generally, in the high frequency device, a higher frequency requires a thinner substrate.

### (Second Main Surface)

A preferred range of the surface roughness Ra of the second main surface 12 is similar to the surface roughness Ra of the first main surface 11. That is, the second main surface 12 has a surface roughness Ra of preferably 10 nm or less, more preferably 3 nm or less, and still more preferably 1 nm or less. Note that, the method for measuring the surface roughness Ra of the second main surface 12 is also similar to that for the first main surface 11.

### (Recessed Portion)

The features of the second recessed portions 16 (not shown) are similar to those of the first recessed portions 15 described above. That is, the second recessed portions 16 (not shown) have an average diameter of preferably 30 μm or less.

The number of the second recessed portions 16 (not shown) is preferably 200/mm² or less, more preferably 100/mm² or less, still more preferably 50/mm² or less, even more preferably 20/mm² or less, particularly preferably 10/mm² or less, even particularly preferably 5/mm² or less, and most preferably 1/mm² or less.

### (Bubble)

Similar to the case of FIG. 2, in a cross-sectional SEM image, a cross-sectional area of the third region 103 is defined as S₃ and a cross-sectional area of the fourth region 104 is defined as S₄. When the bubbles 14 included in the third region 103 are defined as bubbles 143 and the bubbles 14 included in the fourth region 104 are defined as bubbles 144, a total cross-sectional area of the bubbles 143 is defined as S_{b3} and a total cross-sectional area of the bubbles 144 is defined as S_{b4}. Note that, a specific method for calculating S_{b3} and S_{b4} is similar to that for S_{b1} and S_{b2}. In addition, the bubbles 14 present on a boundary of the third region 103 or the fourth region 104 are divided to calculate the cross-sectional area.

At this time, a preferred range of S_{b3}/S₃ is similar to S_{b1}/S₁ described above. That is, S_{b3}/S₃ is preferably 0.15 or less, more preferably 0.13 or less, still more preferably 0.11 or less, even more preferably 0.09 or less, particularly preferably 0.07 or less, extremely preferably 0.05 or less, and most preferably 0.

A preferred range of S_{b4}/S₄ is similar to S_{b2}/S₂ described above. That is, S_{b4}/S₄ is preferably 0.8 or less, more preferably 0.7 or less, still more preferably 0.6 or less, and particularly preferably 0.5 or less.

A preferred range of (S_{b4}/S₄)/(S_{b3}/S₃) is similar to X described above. That is, (S_{b4}/S₄)/(S_{b3}/S₃) is preferably 1.3 or more, more preferably 1.5 or more, still more preferably 1.7 or more, particularly preferably 2.0 or more, and most preferably 2.5 or more.

### <Application>

Hereinafter, applications of the silica glass substrate 10 will be described.

The silica glass substrate 10 can be used as a circuit board by providing a conductor layer on at least one of the first main surface 11 and the second main surface 12 and forming a circuit pattern. In addition, it can also be used as a mounting board in which devices (for example, a semiconductor device or a ceramic device) are mounted on the circuit board. Note that, in order to reduce the size of the circuit board, it is preferable to provide a conductor layer on both the first main surface 11 and the second main surface 12, and in this case, it is preferable to use the silica glass substrate 10 according to the second embodiment shown in FIG. 3.

The conductor layer is made of a conductive metal. Examples of such a metal include gold (Au), silver (Ag), copper (Cu), iron (Fe), nickel (Ni), aluminum (Al), and an alloy thereof. In addition, the conductor layer may be a multilayer structure including a base layer made of titanium (Ti), chromium (Cr), nickel (Ni), or the like, and a wiring layer made of gold (Au), silver (Ag), copper (Cu), or the like.

The devices are, for example, passive devices such as a capacitor and an inductor, and active devices such as a transistor and a diode.

A circuit board or a semiconductor device mounting board including the silica glass substrate 10 can be suitably used for a high frequency device since the silica glass substrate 10 has excellent electrical properties such as a relative dielectric constant and a dielectric loss tangent.

The above circuit board is used in a high frequency device as a transmission line, an antenna, an antenna device in which a transmission line and an antenna are integrated, or the like. Note that, in the description, the “transmission line” refers to a coaxial line, a strip line, a microstrip line, a coplanar line, a parallel line, or the like, and the “antenna” refers to a waveguide slot antenna, a horn antenna, a lens antenna, a printed antenna, a Triplate antenna, a microstrip antenna, a patch antenna, or the like.

In addition, the above semiconductor device mounting board is used as a transmitting and receiving device in a high frequency device.

### <Production Method>

Next, a method for producing the silica glass substrate 10 according to one embodiment will be described.

FIG. 4 is a flowchart showing an example of the method for producing the silica glass substrate 10. The method for producing the silica glass substrate 10 includes steps S31 to S36.

Note that, in the following, a VAD (Vapor-phase Axial Deposition) method is used as a method for synthesizing a silica glass.

The method for synthesizing a silica glass may be changed as appropriate as long as the effects of the present invention are achieved, and the VAD method is preferred since the contents of the OH group and the metal impurities can be reduced.

### (Selection of Synthetic Raw Material)

In step S31, a synthetic raw material for the silica glass is selected.

The synthetic raw material for the silica glass is not particularly limited as long as it is a gasifiable silicon-containing raw material, and examples thereof typically include halogen-containing silicon compounds such as silicon chlorides (such as SiCl₄, SiHCl₃, SiH₂Cl₂, and SiCH₃Cl₃) and silicon fluorides (such as SiF₄, SiHF₃, and SiH₂F₂), and halogen-free silicon compounds such as an alkoxysilane represented by RₙSi(OR)₄₋ₙ (R: an alkyl group having 1 to 4 carbon atoms, n: an integer of 0 to 3) and (CH₃)₃Si—O—Si(CH₃)₃.

### (Formation of Soot Body)

Next, in step S32, a soot body is formed from the above synthetic raw material.

Specifically, the above synthetic raw material is subjected to flame hydrolysis at a temperature of 1000° C. to 1500° C., and the generated silica particles are sprayed and deposited on a rotating base material to form a soot body. In the soot body thus obtained, the silica particles are partly sintered together.

Although not shown, in order to control the electrical properties of the silica glass substrate 10, after step S32, the soot body may be subjected to a heat treatment in a vacuum atmosphere to dehydrate and to reduce the OH-group content. At this time, the temperature during the heat treatment is preferably 1000° C. to 1300° C., and the treatment time is preferably 1 hour to 240 hours.

### (Densification)

Next, in step S33, the above soot body is densified to obtain a silica glass dense body.

Specifically, the above soot body is subjected to a heat treatment in an inert gas atmosphere to promote sintering of the silica particles in the soot body to make it denser, to thereby obtain a silica glass dense body. The silica glass dense body is a transparent silica glass including almost no bubbles or an opaque silica glass including minute bubbles. At this time, the temperature during the heat treatment is preferably 1200° C. to 1700° C., the pressure is preferably 0.01 MPa to 200 MPa, and the treatment time is preferably 10 hours to 100 hours.

In step S33, the above inert gas is dissolved in the silica glass. The inert gas is, for example, a gas containing at least one selected from helium (He), neon (Ne), argon (Ar), krypton (Kr), xenon (Xe), and nitrogen (N₂).

### (Pore Formation)

Next, in step S34, the inside of the silica glass dense body is foamed to be porous, to obtain a silica glass porous body.

Specifically, the above silica glass dense body is subjected to a heat treatment to foam the inert gas dissolved in the silica glass and to thermally expand the bubbles contained in the silica glass dense body, to obtain a silica glass porous body. At this time, the temperature during the heat treatment is preferably 1300° C. to 1800° C., the pressure is preferably 0 Pa to 0.1 MPa, and the treatment time is preferably 1 minute to 20 hours. Note that, in the case where the treatment time is within 20 hours, there is no risk that the bubbles are blocked due to excessive heating.

Hereinafter, a foaming mechanism will be described.

Generally, solubility of the inert gas in the silica glass tends to decrease as the partial pressure of the inert gas in the atmosphere decreases or as the temperature of the silica glass increases. Therefore, in step S34, when a heat treatment is performed in a state where at least one of a lower pressure or a higher temperature than that during the heat treatment in step S33 is satisfied, a dissolved amount of the inert gas is supersaturated, and in this case, and foaming occurs in the silica glass.

In consideration of the above mechanism, foaming may occur even when the temperature during the heat treatment in step S34 is lower than the temperature during the heat treatment in step S33, and it is more preferable that the temperature during the heat treatment in step S34 is higher than the temperature during the heat treatment in step S33 since foaming is promoted. In addition, foaming may occur even when the pressure during the heat treatment in step S34 is higher than the pressure during the heat treatment in step S33, and it is more preferable that the pressure during the heat treatment in step S34 is lower than the pressure during the heat treatment in step S33 since foaming is promoted.

Note that, among the above inert gases, Ar is preferred since it is relatively inexpensive, has a large temperature dependence of the solubility in the silica glass, and allows easy control of foaming.

### (Processing)

Next, in step S35, the above silica glass porous body is processed into any shape using a known method such as cutting, grinding, or polishing to obtain a thin silica glass sheet. Here, the silica glass sheet includes recessed portions formed by the bubbles exposed on the main surface.

In the case of performing polishing, as an abrasive, cerium oxide particles, silicon oxide particles, aluminum oxide particles, zirconium oxide particles, titanium oxide particles, diamond particles, silicon carbide particles, or the like may be used.

### (Melting of Surface Layer)

Next, in step S36, at least one main surface of the above silica glass sheet is scanned with a heat source, such as laser light (for example, CO₂ laser), plasma light, or a combustion flame, to melt and then solidify only a surface layer of the main surface, to reduce the recessed portions, and thus the silica glass substrate 10 is obtained.

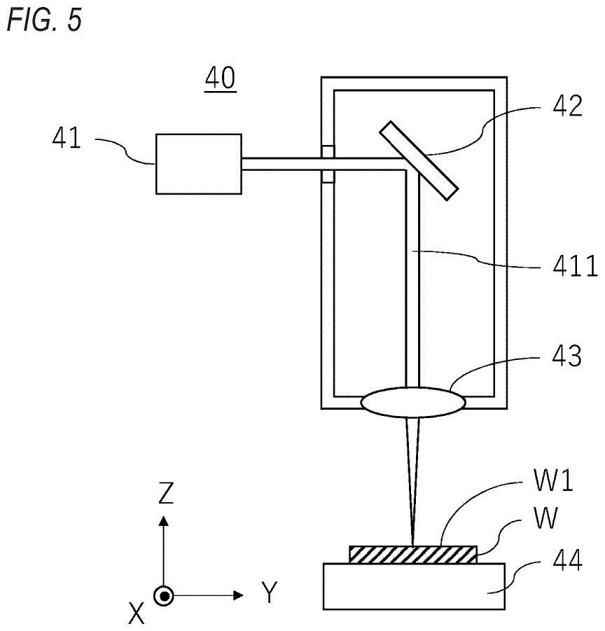

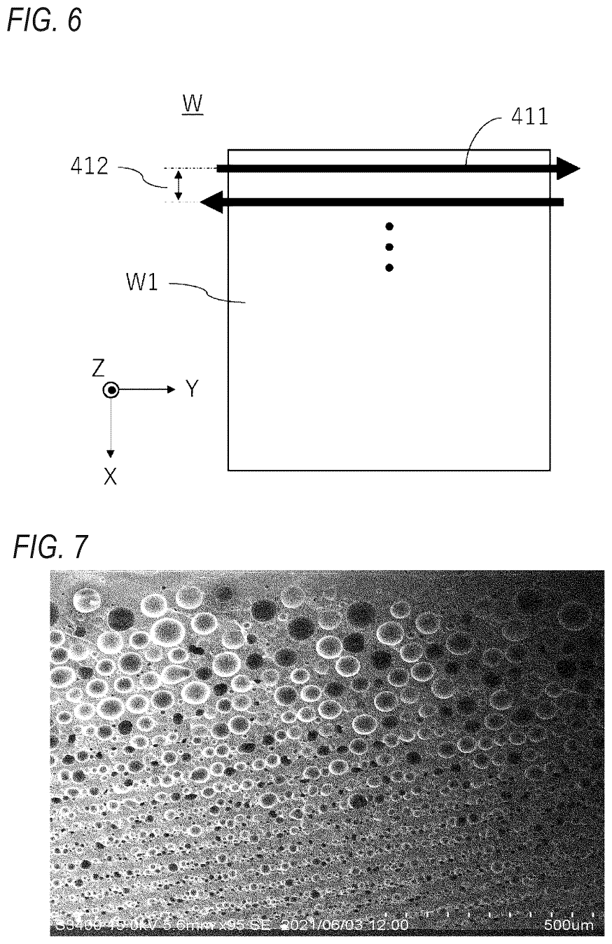

Hereinafter, a method for melting the surface layer when a CO₂ laser is used as the laser light will be specifically described using FIGS. 5 and 6. Note that, in the description, an X axis, a Y axis, and a Z axis defined as shown in FIGS. 5 and 6 may be used.

FIG. 5 is a schematic diagram illustrating a CO₂ laser device 40 according to one embodiment. The CO₂ laser device 40 includes a laser source 41, a mirror 42 that reflects a beam 411 emitted from the laser source 41, a lens 43 that focuses the beam 411 reflected by the mirror 42 on a main surface W1 of a silica glass sheet W, and a stage 44 on which the silica glass sheet W is placed.

FIG. 6 is a schematic diagram illustrating an example of a beam scanning method using the CO₂ laser device 40. As shown in FIG. 6, the CO₂ laser device 40 scans the main surface W1 with the beam 411 by repeatedly moving the beam 411 in the +Y-axis direction, then shifting the beam 411 by an offset 412 in the +X-axis direction, and moving the beam 411 again in the −Y-axis direction. At this time, by controlling a moving speed (hereinafter, also referred to as “scanning speed”) of the beam 411 in the Y direction, a moving distance in the Y direction, and the offset 412, any region on the main surface W1 can be scanned with the beam 411 at any density.

In this way, by scanning any region on the main surface W1 with the beam 411, the surface layer within the region can be melted. After melting, the layer that is molten (hereinafter also referred to as a “molten layer”) is cooled and solidified by allowing to cool or the like. At this time, the molten layer becomes flat due to melting, and then solidifies as it is, so that all or part of the bubbles present in the molten layer disappear (the density of the molten layer increases), and the number of the recessed portions present on the main surface W1 is reduced. At the same time, the bubbles present in a layer directly below the molten layer (hereinafter also referred to as an “expansion layer”) are thermally expanded under the influence of thermal energy during the melting, and the diameter of the bubbles increases (the density of the expansion layer is reduced).

In this way, in the silica glass sheet W including a plurality of bubbles, during the melting, the density of the molten layer increases and at the same time the density of the expansion layer is reduced. As a result, compared to the case where the bubbles in the expansion layer do not expand, the increase in density of the silica glass sheet W due to step S36 is prevented, and it is easy to obtain the silica glass substrate 10 having a small relative dielectric constant. Such an effect is unique to the silica glass sheet W obtained from the above silica glass porous body, and cannot be obtained even when, for example, a step similar to step S36 is performed on a sheet obtained from the above soot body.

The stage 44 can move in the X-axis direction and the Y-axis direction such that the main surface W1 can be freely scanned with the beam 411. In addition, the stage 44 can also move in the Z-axis direction in order to control a beam width of the beam 411 emitted onto the main surface W1. Note that, the shape of the beam 411 emitted onto the main surface W1 is not particularly limited, and may be circular, elliptical, or polygonal.

The mirror 42 may be rotatable about any axis. Although not shown, there may be two or more mirrors 42. Further, the entire CO₂ laser device 40 excluding the stage 44 may be movable in the X-axis, Y-axis, or Z-axis direction. Accordingly, the main surface W1 can also be freely scanned with the beam 411 without moving the stage 44.

The temperature of the silica glass sheet W during irradiation with the beam 411 is not particularly limited, and is preferably 1000° C. to 1300° C., which is around the glass transition temperature.

The temperature of the molten layer during the melting is preferably 1800° C. to 2500° C., and more preferably 2000° C. to 2400° C.

The output of the beam 411 from the laser source 41, the beam width of the beam 411, and the scanning speed of the beam 411 on the main surface W1 may be appropriately adjusted depending on the desired temperature of the molten layer, the depth of the molten layer, or the like.

After step S36, at least one of the first main surface 11 and the second main surface 12 of the silica glass substrate 10 may be further polished in order to reduce the surface roughness Ra. The polishing method is as described above.

From the above, the present description discloses the following silica glass substrate.
[1] A silica glass substrate including:
a first main surface and a second main surface that are facing each other, in which
the silica glass substrate has a density of 2.0 g/cm³ or less,
the silica glass substrate includes a plurality of bubbles,
the silica glass substrate has an average diameter of first recessed portions of 30 μm or less, the first recessed portions being formed by the bubbles exposed on the first main surface, and
the silica glass substrate has the number of the first recessed portions of 200/mm² or less on the first main surface.
[2] The silica glass substrate according to [1], in which the number of the first recessed portions is 100/mm² or less.
[3] The silica glass substrate according to [1] or [2], in which
a region having a depth of 4.93 μm or less from the first main surface is referred to as a first region, and a region having a depth of 19.7 μm to 200 μm from the first main surface is referred to as a second region, and
in a cross-sectional SEM image obtained by observing a cross section obtained by cutting the silica glass substrate along a thickness direction thereof with a scanning electron microscope (SEM), when a cross-sectional area of the first region is defined as S₁, a total cross-sectional area of the bubbles present in the first region is defined as S_{b1}, a cross-sectional area of the second region is defined as S₂, and a total cross-sectional area of the bubbles present in the second region is defined as S_{b2},
the silica glass substrate has S_{b1}/S₁ of 0.15 or less, and (S_{b2}/S₂)/(S_{b1}/S₁) of 1.3 or more.
[4] A silica glass substrate including:
a first main surface and a second main surface that are facing each other, in which
the silica glass substrate has a density of 2.0 g/cm³ or less,
the silica glass substrate includes a plurality of bubbles,
the silica glass substrate has an average diameter of first recessed portions of 30 μm or less, the first recessed portions being formed by the bubbles exposed on the first main surface,
the silica glass substrate has the number of the first recessed portions of 200/mm² or less on the first main surface,
the silica glass substrate has an average diameter of second recessed portions of 30 μm or less, the second recessed portions being formed by the bubbles exposed on the second main surface, and
the silica glass substrate has the number of the second recessed portions of 200/mm² or less on the second main surface.
[5] The silica glass substrate according to [4], in which the number of the first recessed portions and the number of the second recessed portions are each 100/mm² or less.
[6] The silica glass substrate according to [4] or [5], in which
a region having a depth of 4.93 μm or less from the first main surface is referred to as a first region, a region having a depth of 19.7 μm to 200 μm from the first main surface is referred to as a second region, a region having a depth of 4.93 μm or less from the second main surface is referred to as a third region, and a region having a depth of 19.7 μm to 200 μm from the second main surface is referred to as a fourth region, and
in a cross-sectional SEM image obtained by observing a cross section obtained by cutting the silica glass substrate along a thickness direction thereof with a scanning electron microscope (SEM), when a cross-sectional area of the first region is defined as S₁, a total cross-sectional area of the bubbles present in the first region is defined as S_{b1}, a cross-sectional area of the second region is defined as S₂, a total cross-sectional area of the bubbles present in the second region is defined as S_{b2}, a cross-sectional area of the third region is defined as S₃, a total cross-sectional area of the bubbles present in the third region is defined as S_{b3}, a cross-sectional area of the fourth region is defined as S₄, and a total cross-sectional area of the bubbles present in the fourth region is defined as S_{b4},
the silica glass substrate has S_{b1}/S₁ of 0.15 or less, S_{b3}/S₃ of 0.15 or less, (S_{b2}/S₂)/(S_{b1}/S₁) of 1.3 or more, and (S_{b4}/S₄)/(S_{b3}/S₃) of 1.3 or more.
[7] The silica glass substrate according to any one of [1] to [6], having a thickness of 4 mm or less.
[8] A circuit board including:
the silica glass substrate according to any one of [1] to [7]; and
a conductor layer formed on at least one of the first main surface and the second main surface, in which
a circuit pattern is formed on the conductor layer.
[9] A mounting board including:
the circuit board according to [8]; and
a semiconductor device or a ceramic device.

### EXAMPLES

Hereinafter, the present invention will be described in more detail using Examples, but the present invention should not be construed as being limited to these Examples.

### Example 1 to Example 3

Silicon tetrachloride (SiCl₄) was selected as the synthetic raw material for the silica glass, and subjected to flame hydrolysis to generate silica particles. The generated silica particles were sprayed and deposited on a rotating base material to obtain a soot body.

Next, the above soot body was placed in a heating furnace, and the heating furnace was filled with an Ar gas. The soot body was densified at a predetermined temperature, pressure, and treatment time, followed by returning to an atmospheric pressure and allowing to cool. The silica glass dense body obtained at this time was an opaque silica glass including minute bubbles.

Next, the above silica glass dense body was subjected to a heat treatment at a predetermined temperature, pressure, and treatment time, followed by returning to an atmospheric pressure and allowing to cool, to thereby obtain a silica glass porous body.

Next, the above silica glass porous body was taken out from the furnace and subjected to cutting, grinding, and polishing in order to obtain three silica glass sheets (50 mm×50 mm×0.8 mm) according to Example 1 to Example 3.

Next, the silica glass sheets according to Example 1 and Example 2 were placed on the stage 44 of the CO₂ laser device 40 (Diamond E-400 manufactured by Coherent, Inc.), and a CO₂ laser treatment was performed on only one main surface under the conditions shown in Table 1, to obtain the silica glass substrates 10 according to Example 1 and Example 2. On the other hand, the silica glass sheet according to Example 3 was not subjected to a CO₂ laser treatment.

Table 1 shows the conditions for using the CO₂ laser device 40 in Example 1 and Example 2, and the evaluation results for the silica glass substrate 10 or the silica glass sheet according to Example 1 to Example 3. Note that, the parameters were measured by the methods described above.

Note that, Example 1 and Example 2 are Working Examples, and Example 3 is Comparative Example.

TABLE 1

| | | | Exam- | Exam- | Exam- |
|---|---|---|---|---|---|
| | | Unit | ple 1 | ple 2 | ple 3 |
| Conditions | Thickness of | mm | 0.8 | 0.8 | 0.8 |
| | substrate | | | | |
| | Laser output | W | 475 | 475 | — |
| | Beam width | mm | 8 | 0.3 | — |
| | Beam scanning | mm/ | 1000 | 10000 | — |
| | speed | sec | | | |
| | Offset | mm | 0.01 | 0.01 | — |
| Evaluation | Density | g/cm³ | 1.54 | 1.77 | 1.81 |
| | S_{b1}/S₁ | — | 0.01 | 0.12 | 0.18 |
| | S_{b2}/S₂ | — | 0.48 | 0.27 | 0.17 |
| | X | — | 67.11 | 2.21 | 0.94 |
| | Surface roughness | nm | 0.3 | — | 0.57 |
| | Ra | | | | |
| | Number of recessed | /mm² | 0.8 | 76.4 | 769 |
| | portions | | | | |
| | Average diameter of | μm | 21.7 | 6.96 | 4.1 |
| | recessed portions | | | | |
| | Relative dielectric | — | — | 2.7684 | 2.73 |
| | constant (10 GHz) | | | | |
| | Dielectric loss | — | — | 9.0 × | 9.0 × |
| | tangent (10 GHz) | | | 10⁻⁵ | 10⁻⁵ |

### (Evaluation)

FIG. 7 shows a cross-sectional SEM image of the silica glass substrate 10 according to Example 1, obtained using a scanning electron microscope (SEM) (S-3400 manufactured by Hitachi High-Tech Corporation). As can be seen from FIG. 7, in the silica glass substrate 10 according to Example 1, the number of the bubbles 141 present in the first region 101 is significantly reduced by the CO₂ laser treatment, and the diameter of the bubbles 142 present in the second region 102 is increased.

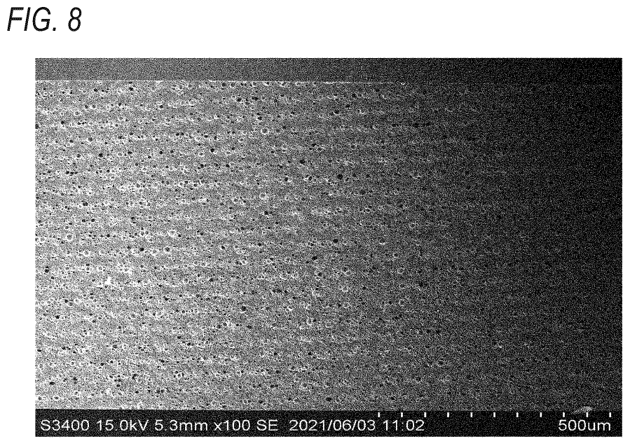

FIG. 8 shows a cross-sectional SEM image of the silica glass sheet according to Example 3, obtained using a scanning electron microscope (SEM) (S-3400 manufactured by Hitachi High-Tech Corporation). As can be seen from FIG. 8, since the silica glass sheet according to Example 3 was not subjected to a CO₂ laser treatment, the bubbles are dispersed substantially uniformly.

As shown in Table 1, since the silica glass substrates 10 according to Example 1 and Example 2 included a plurality of bubbles, S_{b1}/S₁ was 0.15 or less, and X was 1.3 or more, the number of the recessed portions on the first main surface 11 was extremely small. On the other hand, in the silica glass sheet according to Example 3, since S_{b1}/S₁ was more than 0.15 and X was less than 1.3, the first main surface 11 included many recessed portions.

The silica glass substrate 10 according to Example 1 had a value of surface roughness Ra smaller than that of the silica glass sheet according to Example 3.

As can be seen from comparison between the silica glass substrate 10 according to Example 2 and the silica glass sheet according to Example 3, the CO₂ laser treatment does not deteriorate the values of the relative dielectric constant and the dielectric loss tangent.

From the above, it can be seen that the silica glass substrates 10 according to Example 1 and Example 2 are more suitable as a substrate for a high frequency device than the silica glass sheet in Example 3, which was not subjected to a CO₂ laser treatment.

Although the silica glass substrate according to one embodiment of the present invention has been described above, the present invention is not limited to the above embodiment. Various changes, modifications, substitutions, additions, deletions, and combinations are possible within the scope of claims. These also naturally belong to the technical scope of the present invention.

The present application is based on a Japanese Patent Application (Japanese Patent Application No. 2022-022213) filed on Feb. 16, 2022, and the contents thereof are incorporated herein by reference.

### REFERENCE SIGNS LIST

10 silica glass substrate
101 first region
102 second region
11 first main surface
12 second main surface
13 silica glass portion
14 bubble
15 first recessed portion

1. A silica glass substrate comprising:
a first main surface and a second main surface that are facing each other, wherein
the silica glass substrate has a density of 2.0 g/cm³ or less,
the silica glass substrate comprises a plurality of bubbles,
the silica glass substrate has an average diameter of first recessed portions of 30 μm or less, the first recessed portions being formed by the bubbles exposed on the first main surface, and
the silica glass substrate has the number of the first recessed portions of 200/mm² or less on the first main surface.

2. The silica glass substrate according to claim 1, wherein the number of the first recessed portions is 100/mm² or less.

3. The silica glass substrate according to claim 1, wherein
a region having a depth of 4.93 μm or less from the first main surface is referred to as a first region, and a region having a depth of 19.7 μm to 200 μm from the first main surface is referred to as a second region, and
in a cross-sectional SEM image obtained by observing a cross section obtained by cutting the silica glass substrate along a thickness direction thereof with a scanning electron microscope (SEM), when a cross-sectional area of the first region is defined as S₁, a total cross-sectional area of the bubbles present in the first region is defined as S_{b1}, a cross-sectional area of the second region is defined as S₂, and a total cross-sectional area of the bubbles present in the second region is defined as S_{b2},
the silica glass substrate has S_{b1}/S₁ of 0.15 or less, and (S_{b2}/S₂)/(S_{b1}/S₁) of 1.3 or more.

4. A silica glass substrate comprising:
a first main surface and a second main surface that are facing each other, wherein
the silica glass substrate has a density of 2.0 g/cm³ or less,
the silica glass substrate comprises a plurality of bubbles,
the silica glass substrate has an average diameter of first recessed portions of 30 μm or less, the first recessed portions being formed by the bubbles exposed on the first main surface,
the silica glass substrate has the number of the first recessed portions of 200/mm² or less on the first main surface,
the silica glass substrate has an average diameter of second recessed portions of 30 μm or less, the second recessed portions being formed by the bubbles exposed on the second main surface, and
the silica glass substrate has the number of the second recessed portions of 200/mm² or less on the second main surface.

5. The silica glass substrate according to claim 4, wherein the number of the first recessed portions and the number of the second recessed portions are each 100/mm² or less.

6. The silica glass substrate according to claim 4, wherein
a region having a depth of 4.93 μm or less from the first main surface is referred to as a first region, a region having a depth of 19.7 μm to 200 μm from the first main surface is referred to as a second region, a region having a depth of 4.93 μm or less from the second main surface is referred to as a third region, and a region having a depth of 19.7 μm to 200 μm from the second main surface is referred to as a fourth region, and
in a cross-sectional SEM image obtained by observing a cross section obtained by cutting the silica glass substrate along a thickness direction thereof with a scanning electron microscope (SEM), when a cross-sectional area of the first region is defined as S₁, a total cross-sectional area of the bubbles present in the first region is defined as S_{b1}, a cross-sectional area of the second region is defined as S₂, a total cross-sectional area of the bubbles present in the second region is defined as S_{b2}, a cross-sectional area of the third region is defined as S₃, a total cross-sectional area of the bubbles present in the third region is defined as S_{b3}, a cross-sectional area of the fourth region is defined as S₄, and a total cross-sectional area of the bubbles present in the fourth region is defined as S_{b4},
the silica glass substrate has S_{b1}/S₁ of 0.15 or less, S_{b3}/S₃ of 0.15 or less, (S_{b2}/S₂)/(S_{b1}/S₁) of 1.3 or more, and (S_{b4}/S₄)/(S_{b3}/S₃) of 1.3 or more.

7. The silica glass substrate according to claim 1, having a thickness of 4 mm or less.

8. The silica glass substrate according to claim 4, having a thickness of 4 mm or less.

9. A circuit board comprising:
the silica glass substrate according to claim 1; and
a conductor layer formed on at least one of the first main surface and the second main surface, wherein
a circuit pattern is formed on the conductor layer.

10. A mounting board comprising:
the circuit board according to claim 9; and
a semiconductor device or a ceramic device.

11. A circuit board comprising:
the silica glass substrate according to claim 4; and
a conductor layer formed on at least one of the first main surface and the second main surface, wherein
a circuit pattern is formed on the conductor layer.

12. A mounting board comprising:
the circuit board according to claim 11; and
a semiconductor device or a ceramic device.
